(19) United States
(12) Patent Application Publication
(10) Pub. No.: US 2010/0230622 A1
(43) Pub. Date: Sep. 16, 2010

(54) PIEZOELECTRIC ACTUATOR

(76) Inventor: Friedrich Boecking, Stuttgart (DE)

Correspondence Address: RONALD E. GREIGG;GREIGG & GREIGG P.L.L.C., 1423 POWHATAN STREET, UNIT ONE, ALEXANDRIA, VA, 22314, US

(21) Appl. No.: 12/303,891

(22) PCT Filed: May 22, 2007
(86) PCT No.: PCT/EP2007/054949

§ 371 Date: Dec. 8, 2008

(30) Foreign Application Priority Data
Jun. 8, 2006 (DE) 10 2006 026 643.9

(51) Int. Cl. F16K 31/02; H01L 41/047; H01L 41/083

(52) U.S. Cl. 251/129.06; 310/366

(57) ABSTRACT

A piezoelectric actuator for a fuel injection valve has an actuator body with a multiplicity of ceramic layers and a multiplicity of electrode layers which are arranged between the ceramic layers. In this case, an external electrode is provided which is connected to some of the electrode layers. The external electrode has a plurality of longitudinal wires, which run in the longitudinal direction of the actuator body, and a plurality of weft wires, wherein a weft wire is passed through the longitudinal wires in such a way that some of the longitudinal wires run above the weft wire and other longitudinal wires run beneath the weft wire.

### PRIOR ART

The invention relates to a piezoelectric actuator for a fuel injection valve and a fuel injection valve equipped with such a piezoelectric actuator. In particular, the invention relates to the field of injectors for fuel injection systems of air-compressing autoignition internal combustion engines.

DE 199 28 189 A1 has disclosed a piezoelectric actuator for actuating a valve. The known piezoelectric actuator has external electrodes in which a first layer of the external electrode is composed of a metal surface and a second layer of the external electrode is embodied in the form of a net-like or weave-like layer. The two layers are connected to each other, for example, at discrete points, leaving a stretchable region between the contacts. The net-like or weave-like external electrode layer serves to prevent the transverse tearing away from the internal electrodes that can occur due to delamination; thanks to the soldering at discrete points, no powerful shear stresses occur in the external electrodes with the expansion of the piezoelectric actuator.

The piezoelectric actuator known from DE 199 28 189 A1 has the disadvantage that stresses occurring in the external electrode with the expansion of the piezoelectric actuator are distributed over a small number of contact points so that the powerful stress on the contact points can damage them. In addition, the embodiment of the external electrodes in the known piezoelectric actuator is complex and therefore entails high manufacturing costs.

### DISCLOSURE OF THE INVENTION

### Advantageous Effects

The piezoelectric actuator according to the invention with the defining characteristics of claim 1 and the fuel injection valve according to the invention with the defining characteristics of claim 14 have the advantage over the prior art of having a reliable contacting between the external electrode and the ceramic layers while being inexpensive to manufacture.

Advantageous modifications of the piezoelectric actuator disclosed in claim 1 and of the fuel injection valve disclosed in claim 14 are possible by means of the measures taken in the dependent claims.

It is advantageous that the warp wires extend next to one another and that the weft wire is routed through the warp wires in such a way that of two warp wires extending next to each other, one travels over the weft wire and the other travels under it. The warp wires in this case can be embodied as sinuous warp wires while the weft wires are embodied as approximately straight weft wires. This has the advantage that a relatively dense, web-like structure of the external electrode is achieved, which is stretchable in the longitudinal direction, withstands powerful stresses, and permits a reliable connection to the electrode layers of the actuator body.

It is also advantageous that the weft wires have a larger diameter than the warp wires; the diameter of the weft wires is preferably x times the diameter of the warp wires, where x is greater than 1.0 and less than or equal to 3. In this embodiment, thin, flexible warp wires embodied in the form of travel wires loop around relatively rigidly embodied weft wires, thus yielding a flexible structure of the external electrode that withstands powerful stresses.

The warp wires and weft wires can be composed of the same materials or also of different materials. Preferably, the weft wires are composed of brass, copper, silver, or a combination of these materials, while the warp wires are preferably manufactured out of an Invar alloy. Such an Invar alloy can be composed, for example, of a steel with a 36% nickel content so that the warp wires experience little or no stretching when heated.

The weft wires can extend in a transverse direction, i.e. perpendicular to the longitudinal direction, or can also be routed through the warp wires at a certain angle in relation to the transverse direction so that the weft wires extend in a direction that encloses an angle with the longitudinal direction that is greater than 0° and less than 90°.

The structure of the external electrode composed of warp and weft wires can be attached to the electrode layers of the actuator body in a suitable fashion, in particular by means of soldering. This soldered attachment can in this case be embodied as relatively large in area and is not necessarily limited to a few contact points; the flexible structure assures the flexibility of the external electrode with regard to the expansion of the actuator body during actuation of the actuator.

### BRIEF DESCRIPTION OF THE DRAWINGS

Preferred exemplary embodiments of the invention are explained in greater detail in the following description in conjunction with the accompanying drawings in which corresponding elements are provided with coinciding reference numerals.

FIG. 1 is a schematic sectional depiction of a fuel injection valve equipped with a piezoelectric actuator according to a first exemplary embodiment of the invention;

FIG. 2 shows the detail labeled II in FIG. 1 of the piezoelectric actuator of the fuel injection valve of the first exemplary embodiment of the invention;

FIG. 3 shows a detail of a piezoelectric actuator of a fuel injection valve according to the first exemplary embodiment of the invention, viewed from the direction labeled I in FIG. 2, and

FIG. 4 shows the detail shown in FIG. 3 of a piezoelectric actuator of a fuel injection valve according to a second exemplary embodiment of the invention.

### EMBODIMENTS OF THE INVENTION

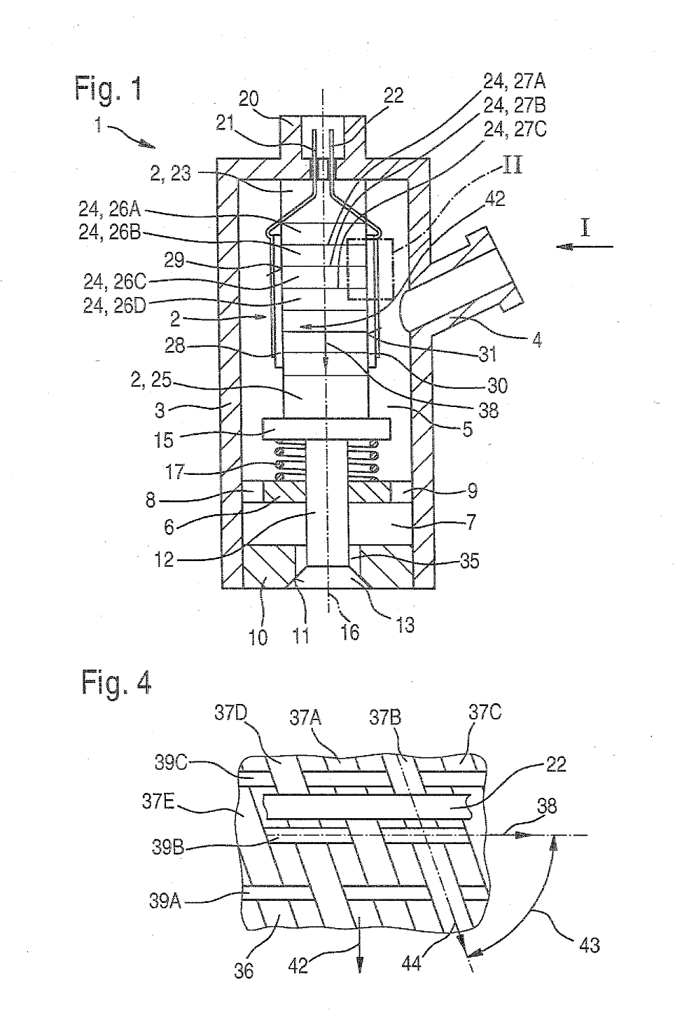

FIG. 1 shows a fuel injection valve 1 equipped with a piezoelectric actuator 2 according to a first exemplary embodiment of the invention. The fuel injection valve 1 can in particular serve as an injector for fuel injection systems of mixture-compressing autoignition internal combustion engines. A preferred use of the fuel injection valve 1 is for a fuel injection system with a common rail that delivers diesel fuel at high pressure to a plurality of fuel injection valves 1. The piezoelectric actuator 2 according to the invention is particularly suitable for such a fuel injection valve 1. The fuel injection valve 1 according to the invention and the actuator 2 according to the invention are, however, also suitable for other practical applications.

The fuel injection valve 1 has a valve housing 3 with a fuel inlet fitting 4. The fuel inlet fitting 4 can be connected to a fuel line in order to convey fuel into an actuator chamber 5 provided inside the valve housing 3. A housing part 6 separates the actuator chamber 5 from a fuel chamber 7 likewise provided inside of the valve housing 3; the housing part 6 has through openings 8, 9 in order to convey the supplied fuel via the actuator chamber 5 into the fuel chamber 7.

On a valve seat body 10 that is connected to the valve housing 3, a valve seat surface 11 is provided that cooperates with a valve closure member 13, which the piezoelectric actuator 2 can actuate by means of a valve needle 12, to form a sealing seat. The valve closure member 13 in this case is connected via the valve needle 12 to a pressure plate 15 that is situated inside the actuator chamber 5. The housing part 6 also guides the valve needle 12 in the axial direction, i.e. in the direction of an axis 16 of the valve housing 3 of the fuel injection valve 1. Also provided inside the actuator chamber 5 is a valve spring 16 that exerts a closing force on the valve closure member 13 via the pressure plate 15 and the valve needle 12, thus closing the sealing seat formed between the valve closure member 13 and the valve seat surface 11.

The valve housing 3 is also provided with a connection element 20 for connecting the fuel injection valve 1 to an electrical supply line; the electrical supply line can be connected to electrical lines 21, 22 by means of a plug connector. The electrical lines 21, 22 are routed through the valve housing 3 and an actuator foot 23 of the actuator 2 to an actuator body 24 of the actuator 2. The actuator 2 also has an actuator head 25.

The actuator body 24 of the piezoelectric actuator 2 has a multitude of ceramic layers 26A, 26B, 26C, 26D and a multitude of electrode layers 27A, 27B, 27C situated between the ceramic layers 26A through 26D. Only the ceramic layers 26A through 26D and the electrode layers 27A through 27C are shown here for the sake of simplicity. One portion of the electrode layers 27A, 27B, 27C is connected to the electrical line 21 via an external electrode 28; the external electrode 28 is connected to the actuator body 24 at an outside 29 of the actuator body 24 and in the exemplary embodiment shown, is connected to the electrode layer 27B. Another portion of the electrode layers 27A through 27C is connected to the electrical line 22 via an external electrode 30; the external electrode 30 is connected to the actuator body 24 at an outside 31 of the actuator body 24 and is connected to the electrode layers 27A, 27C.

The actuator 2 can be charged via the electrical lines 21, 22, causing it to expand along the axis 16, thus opening the sealing seat formed between the valve closure member 13 and the valve seat surface 11. This causes the injection of fuel from the fuel chamber 7 via an annular gap 35 and the open sealing seat. When the actuator 2 is switched into the powerless state, it then contracts again, thus reclosing the sealing seat formed between the valve closure member 13 and the valve seat surface 11.

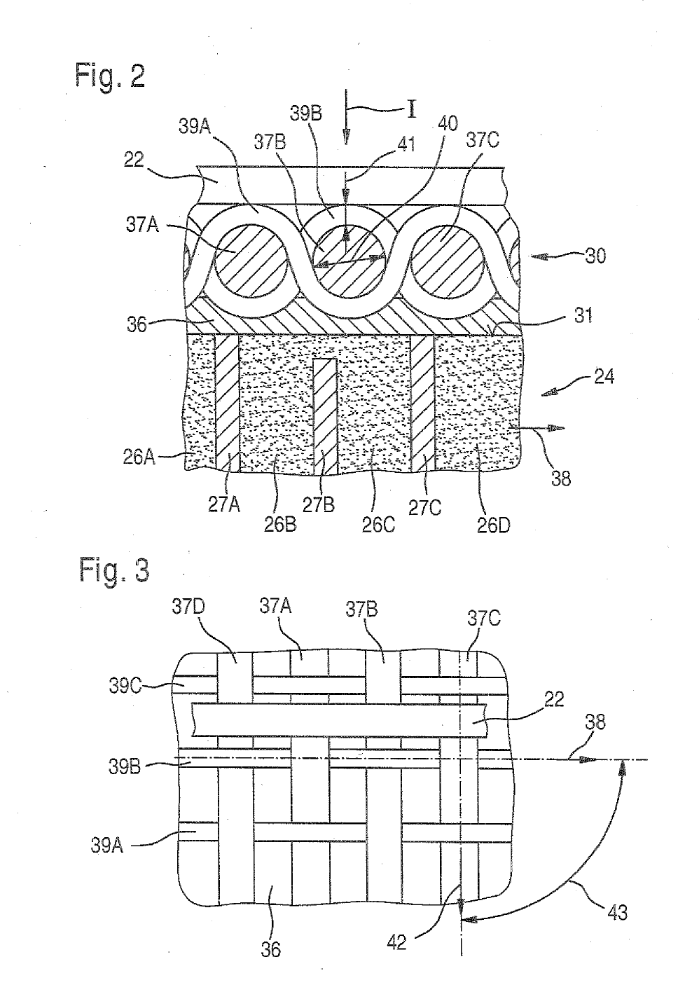

The electrode layers 27B connected to the electrical line 21 via the external electrode 28 can, for example, constitute the positive electrode layers 27B while the electrode layers 27A, 27C connected to the electrical line 22 via the external electrode 30 can constitute the negative electrode layers 27A, 27C. The connection of the electrode layers 27A, 27C to the electrical line 22 will be described in detail in conjunction with FIGS. 2 and 3. The connection of the electrode layers 2B to the electrical line 21 via the external electrode 28 can occur in a corresponding fashion.

FIG. 2 shows a schematic sectional view of the detail labeled II in FIG. 1 of a piezoelectric actuator 2 of a fuel injection valve 1. The actuator body 24 has an outside 31 and the electrode layers 27A, 27C extend to the outside 31 while the electrode layer 27B is spaced slightly apart from the outside 31. In relation to the outside 29 of the actuator body 24 shown in FIG. 1, which is situated on the opposite side from the outside 31, the electrode layer 27B extends to the outside 29 while the electrode layers 27A, 27C are spaced slightly apart from the outside 29. The external electrode 30 is connected to the electrode layers 27A, 27C by means of a connecting layer 36; the connecting layer 36 is composed, for example, of a solder in order to solder the external electrode 30 to the electrode layers 27A, 27C. The external electrode 30 has weft wires 37A, 37B, 37C situated next one another and extending parallel to one another. The external electrode 30 also has warp wires 39A, 39B extending in a longitudinal direction 38 of the actuator body 24. The warp wires 39A, 39B in this case extend next one another and are each embodied as sinuous. Consequently, the warp wire 39A first travels over the weft wire 37A, then under the weft wire 37B, and then over the weft wire 37C. By contrast, the warp wire 39B, which is situated next to the warp wire 39A, first travels under the weft wire 37A, then over the weft wire 37B, and then under the weft wire 37C.

A diameter 40 of the weft wire 37B is selected to be greater than a diameter 41 of the warp wire 39A. In this exemplary embodiment, all of the weft wires 37A, 37B, 37C have at least approximately the same diameter 40. The warp wires 39A, 39B likewise have the same diameter 41, thus yielding an average diameter 41 of the warp wires 39A, 39B. The average diameter 40 of the weft wires 37A through 37C is x times the average diameter 41 of the warp wires 39A, 39B, where x is greater than 1.0 and less than or equal to 3. Consequently, the relatively thin and flexible warp wires 39A, 39B loop around the relatively rigid, essentially straight weft wires 37A through 37C.

The electrical line 22 is connected in a suitable fashion, for example by means of soldering or welding, to the external electrode 30, in particular the weft wires 37A through 37C, and/or the warp wires 39A, 39B.

FIG. 3 shows a detail of the piezoelectric actuator 2 of the fuel injection valve 1 according to the first exemplary embodiment, viewed from the direction labeled I in FIGS. 1 and 2. In this case, an additional weft wire 37D is shown that extends next to the weft wire 37A. Furthermore, an additional warp wire 39C is shown, which extends next to the warp wire 39B and is routed around the weft wires 37A through 37D in a manner that corresponds to that of warp wire 39A.

The weft wire 37C extends in a transverse direction 42 that is oriented perpendicular to the longitudinal direction 38 so that the transverse direction 42 in which the weft wire 37C extends encloses an angle 43 of 90° with the longitudinal direction 38. The weft wires 37A, 37B, 37D extend parallel to the weft wire 37C so that they also extend in the transverse direction 42 and are thus oriented perpendicular to the longitudinal direction 38. During operation of the fuel injection valve 1, the longitudinal direction 38 of the actuator body 24 coincides with a stroke direction of the actuator body 24. In addition, the longitudinal direction 38 in the fuel injection valve 1 shown in FIG. 1 is oriented in the direction of the axis 16 of the valve housing 3.

In the same detail of a piezoelectric actuator 2 of a fuel injection valve 1 shown in FIG. 3, FIG. 4 shows a second exemplary embodiment of the invention. In this case, an additional weft wire 37E is shown, which is situated next to the weft wire 37D and extends parallel to the weft wire 37D.

The weft wires 37A through 37E extend parallel to one another in a direction 44 that differs from the transverse direction 42; the weft wires 37A through 37E extend only partially in the transverse direction 42. In this case, an angle 43 that is greater than 0° and less than 90° is enclosed by the direction 44 in which the weft wires 37A through 37E extend and the longitudinal direction 38 in which the warp wires 39A through 39C extend.

In the exemplary embodiments shown in FIGS. 3 and 4, each of the weft wires 37A through 37E is routed through the warp wires 39A, 39B, 39C in such a way that of two warp wires 39A, 39B, 39C extending next to each other, one travels over the respective weft wire 37A through 37E and the other travels under it. The weft wires 37A through 37E are embodied as rigid weft wires that can be composed of materials such as brass, copper, and/or silver. The warp wires 39A through 39C are preferably embodied as flexible; embodying them out of an Invar alloy, for example with a 36% nickel content, is advantageous in order to prevent a temperature-induced expansion of the warp wires 39A through 39C during operation of the fuel injection valve 1.

The invention is not limited to the exemplary embodiments described herein.

1-14. (canceled)

15. A piezoelectric actuator, in particular an actuator for fuel injection valves, comprising:
an actuator body that is equipped with a multitude of ceramic layers and a multitude of electrode layers situated between the ceramic layers; and
at least one external electrode that is connected to a portion of the electrode layers of the actuator body, the external electrode having a plurality of warp wires extending at least essentially in a longitudinal direction of the actuator body and a plurality of weft wires, wherein the weft wires are routed through the warp wires in such a way that a portion of a warp wires extend above a weft wire and a portion of the warp wires extend below the weft wire.

16. The piezoelectric actuator as recited in claim 15, wherein the warp wires extend at least essentially next to one another and the weft wire is routed through the warp wires in such a way that of two warp wires extending next to each other, one travels over the weft wire and an other travels under it.

17. The piezoelectric actuator as recited in claim 15, wherein the warp wires are at least approximately embodied in the form of sinuous warp wires.

18. The piezoelectric actuator as recited in claim 16, wherein the warp wires are at least approximately embodied in the form of sinuous warp wires.

19. The piezoelectric actuator as recited in claim 15, wherein the weft wires are at least approximately embodied in the form of a straight weft wire.

20. The piezoelectric actuator as recited in claim 16, wherein the weft wires are at least approximately embodied in the form of a straight weft wire.

21. The piezoelectric actuator as recited in claim 18, wherein the weft wires are at least approximately embodied in the form of a straight weft wire.

22. The piezoelectric actuator as recited in claim 15, wherein the weft wires are routed through the warp wires at least parallel to one another and that a warp wire travels over one of the weft wires and under one of the weft wires in alternating fashion in the longitudinal direction.

23. The piezoelectric actuator as recited in claim 21, wherein the weft wires are routed through the warp wires at least parallel to one another and that a warp wire travels over one of the weft wires and under one of the weft wires in alternating fashion in the longitudinal direction.

24. The piezoelectric actuator as recited in claim 15, wherein the weft wires have an average diameter that is greater than an average diameter of the warp wires.

25. The piezoelectric actuator as recited in claim 23, wherein the weft wires have an average diameter that is greater than an average diameter of the warp wires.

26. The piezoelectric actuator as recited in claim 24, wherein the average diameter of the weft wires is x times the average diameter of the warp wires, where x is greater than 1 and less than or equal to 3.

27. The piezoelectric actuator as recited in claim 25, wherein the average diameter of the weft wires is x times the average diameter of the warp wires, where x is greater than 1 and less than or equal to 3.

28. The piezoelectric actuator as recited in claim 15, wherein the warp wires are embodied as flexible warp wires.

29. The piezoelectric actuator as recited in claim 28, wherein the warp wires are composed of a material that contains an Invar alloy.

30. The piezoelectric actuator as recited in claim 15, wherein the weft wires are embodied as rigid weft wires.

31. The piezoelectric actuator as recited in claim 30, wherein the weft wires are composed of a material that contains brass and/or copper and/or silver.

32. The piezoelectric actuator as recited in claim 15, wherein the weft wires extend in a transverse direction of the actuator body and the transverse direction is oriented perpendicular to the longitudinal direction.

33. The piezoelectric actuator as recited in claim 15, wherein the weft wires extend in a direction that encloses an angle with the longitudinal direction that is greater than 0° and less than 90°.

34. A fuel injection valve, in particular an injector for fuel injection systems of air-compressing autoignition internal combustion engines, comprising:
a piezoelectric actuator as recited in claim 15; and
a valve closure member that is actuatable by the piezoelectric actuator and which cooperates with a valve seat surface to form a sealing seat.
